(19) United States
(12) Patent Application Publication
(10) Pub. No.: US 2025/0364773 A1
(43) Pub. Date: Nov. 27, 2025

(54) METHOD FOR THE SPECTRAL POSITIONING OF A PHOTONIC SYSTEM AND PHOTONIC SYSTEM CARRYING OUT SUCH A METHOD

(71) Applicant: SCINTIL PHOTONICS, GRENOBLE (FR)

(72) Inventors: Sylvie Menezo, Grenoble (FR); Florian Enault

(73) Assignee: SCINTIL PHOTONICS, GRENOBLE (FR)

(21) Appl. No.: 18/855,561

(22) PCT Filed: Jan. 13, 2023
(86) PCT No.: PCT/EP2023/050716

§ 371 Date: Aug. 11, 2025

(30) Foreign Application Priority Data
May 24, 2022 (FR) FR2204950
Jul. 25, 2022 (FR) FR2207600

(51) Int. Cl. H01S 3/13

(52) U.S. Cl. CPC H01S 3/1305

(57) ABSTRACT

The invention relates to a method for the spectral positioning of a photonic system, the photonic system carrying out the steps of conditioning a control signal (V) in order to produce a digital control signal, carrying out a first step (OP1) of processing the digital control signal in order to produce at least one digital signal, which digital signal is referred to as the “first locking signal”, representative of the power of a second harmonic or the main component of the modulation frequency (Fd) present in the digital control signal, carrying out a second step (OP2) of processing the first locking signal (Vr1) in order to produce a digital adjustment command, the second step (OP2) being intended to optimize the amplitude of the first locking signal, (Vr1) and conditioning the digital adjustment command in order to produce the adjustment command (CLa) and apply the adjustment command to the adjustment device (H1).

### FIELD OF THE INVENTION

The invention concerns a photonic system. More specifically, the invention relates to a method for the spectral positioning of a photonic device comprising at least one laser source and one filter. The filter can be a resonant ring filter, a Mach Zehnder (MZ) interferometer filter, or may form, at least in part, a resonant ring modulator or an MZ modulator.

### BACKGROUND OF THE INVENTION

The state of the art includes numerous methods for aligning the resonant frequency of an optical filter with the emission frequency of a laser source. The adjustment of the resonant frequency or emission frequency can be carried out using a heater placed close to the filter or laser. The heater is controlled in such a way as to “lock” the system, that is, to match the emission frequency to the resonant frequency.

In “Error-free operation of a polarization-insensitive 4λ; ×25 Gbps silicon photonic WDM receiver with closed-loop thermal stabilization of Si microrings,” Opt. Express 24, 13204-13209 (2016) a photodetector and a heater are associated with each filter in the system. A controller measures the current supplied by the photodetector at regular intervals and incrementally adjusts the heater control in order to maximize the current produced, thus seeking to align the laser emission frequency with the filter resonant frequency. Each filter (or group of filters) in the system has its own control loop (including heater and photodetector) and is therefore individually locked.

The paper “Wavelength Locking and Thermally Stabilizing Microring Resonators Using Dithering Signals,” in Journal of Lightwave Technology, vol. 32, No. 3, pp. 505-512, Feb. 1, 2014 also proposes a method for spectral positioning of a similar photonic system, including a plurality of filters fitted with heaters and photodetectors. According to the approach disclosed in this document, the resonant frequencies of the filters are modulated using a square-wave modulation signal. For each filter, an analog circuit calculates the product between the signal supplied by the photodetector and the modulation signal, filters out the harmonics and retains only the static part of this product to identify, according to the sign of this static part, whether the emission frequency is below or above the resonant frequency. This information is used to adjust the control applied to the heater in order to reduce the difference between these two frequencies.

With this approach, each filter in the photonic system also has its own control loop (including heater and photodetector) and is therefore individually locked.

When the photonic system has several channels, that is, several resonant frequencies and/or several emission frequencies that need to be locked together, these methods require as many photodetectors as channels. The presence of a photodetector for each channel to be locked makes these approaches particularly complex to implement, especially when the number of channels is large, e.g., greater than 10 or 50. On the other hand, the approach whereby the modulation frequency applies to the filter and its resonant frequency can lead to multiple filters being locked to a single emission frequency, whereas it is generally desirable to lock each filter to its own emission frequency in order to form independent channels.

The paper “Simultaneous wavelength locking of microring modulator array with a single monitoring signal,” Opt. Express 25, 16040-16046 (2017) proposes a technique for simultaneously locking the resonant frequencies of an array of ring modulators to the spectral lines of a frequency comb light beam. As is well known, a ring modulator both filters a selected wavelength from a number of wavelengths and modulates that selected wavelength. In the aforementioned document, locking is achieved by means of a single photodetector that taps the power of the radiation circulating in an optical bus to which the modulators are coupled and wherein a modulated WDM optical signal circulates. An optimization algorithm exploits the RF part of the optical power of the radiation, that is, the power generated by the modulators, in order to establish the control signals for the heaters respectively associated with these modulators, the controls aiming to maximize the RF optical power present in the optical bus.

When the optimization algorithm is initialized, each modulator is adjusted consecutively in an exhaustive search until there is a noticeable gradient in the measured RF power. At this point, a gradient method takes over for rapid convergence to the best heating bias. During this process, each modulator is locked. Once the last ring modulator has been adjusted, the algorithm uses the endless gradient method on each ring to track the temperature drift.

The approach followed in this paper is based on the assumption that RF optical power is at its maximum when the resonant frequencies of the modulators are well aligned with the emission frequencies forming the spectral lines of the radiation. For this assumption to be satisfied, it is essential that the data modulated by each modulator is uncorrelated. This approach also requires emission frequencies to be well separated from one another by at least 50 GHz to avoid locking several modulators to a single emission frequency.

Another approach, based on a single photodetector and modulation of filter resonant frequencies, is presented in the paper “Streamlined Architecture for Thermal Control and Stabilization of Cascaded DWDM Micro-Ring Filters Bus,” presented by Maarten Hattink at the Optical Fiber Conference, Mar. 6-10, 2022. However, this approach requires calibration of the device, which makes the solution particularly cumbersome to operate. The choice of modulation frequencies proposed in this document leads to the introduction of error terms on the feedback signals. This configuration runs the risk of locking several modulators to a single emission frequency.

### OBJECT OF THE INVENTION

One aim of the invention is to propose a method for spectral positioning of a photonic system which does not have the limitations of the state of the art and which differs from it. More specifically, one aim of the invention is to propose a spectral positioning system that does not require as many photodetectors as channels to be locked. Another aim of the invention is to provide a locking means that avoids locking multiple filters to a single emission frequency of a multispectral radiation source.

### BRIEF DESCRIPTION OF THE INVENTION

In order to achieve this aim, the object of the invention proposes a method for the spectral positioning of a photonic system, the photonic system comprising
at least one laser source producing radiation with at least one emission frequency;
a plurality of filters each having a resonant frequency;
at least one waveguide configured to optically couple the radiation produced by the laser source to the filters;
a photodetector optically coupled to the waveguide to receive filtered radiation, the photodetector producing a control signal;
a plurality of adjustment devices associated with the laser source and/or the filters, the adjustment devices being controlled on the one hand to modulate, at a modulation frequency, the emission frequency of the laser source or the resonant frequencies of the filters, and on the other hand to adjust the resonant frequency of the filters;

the method implementing the following operations:
conditioning the control signal in order to produce a digital control signal;
first processing operation on the digital control signal in order to produce at least one digital signal, referred to as the “first locking signal,” representative of the power of a second harmonic and/or a main component of the modulation frequency present in the digital control signal;
a second operation of processing the first locking signal in order to produce a digital adjustment command, the second operation being intended to optimize the amplitude of the first locking signal;
conditioning the digital adjustment command in order to produce the adjustment command and apply it to the adjustment devices.

According to other advantageous non-limiting features of the invention, taken alone or according to any technically feasible combination:
the first locking signal is representative of the power of a second harmonic of the modulation frequency and the second operation is designed to maximize the amplitude of the first locking signal, or the first locking signal is representative of the power of the main component of the modulation frequency and the second operation is designed to minimize the amplitude of the first locking signal;
the first locking signal is formed by the ratio between the power of the second harmonic of the modulation frequency and the power of the main component of the modulation frequency, the second operation being designed to optimize the amplitude of the first locking signal so that it is equal to or greater than a specified value;
the first operation produces at least a second locking signal representative of the phase of the digital control signal of a main component of the modulation frequency present in the digital control signal;
the second locking signal corresponds to the difference between the phase of a main component of the modulation frequency present in the digital control signal and the phase of a modulation signal or reference signal;
the first operation comprises a Fourier transform of the digital control signal;
the method comprises a step of selecting a single one of the adjustment devices, the selection step being repeated to successively select each of the adjustment devices;
the modulation frequencies of the adjustment devices are distinct from one another;
the adjustment command is applied to the adjustment devices one optical filter at a time.

According to another aspect, the object of the invention proposes a photonic system for spectral positioning of a photonic device comprising:
at least one laser source producing radiation with at least one emission frequency;
a plurality of filters each having a resonant frequency;
at least one waveguide configured to optically couple the radiation produced by the laser source to the filter;
a photodetector optically coupled to the waveguide to receive filtered radiation, the photodetector producing a control signal;
a plurality of adjustment devices associated with the laser source and/or the filters, the adjustment devices being controlled to modulate, at a modulation frequency, the emission frequency of the laser source or the resonant frequencies of the filters, on the one hand, and to adjust the resonant frequency of the filters, on the other;
a locking device configured to perform the following operations:
   i. conditioning the control signal to produce a digital control signal;
   ii. a first processing operation on the digital control signal to produce at least one digital signal, referred to as the “first locking signal,” representative of the power of a second harmonic and/or a main component of the modulation frequency present in the digital control signal;
   iii. a second operation for processing the first locking signal to produce a digital adjustment command, the second operation being aimed at optimizing the amplitude of the first locking signal;
iv. conditioning the digital adjustment command to produce the adjustment command and apply it to the adjustment devices.

According to other advantageous non-limiting features of the invention, taken alone or according to any technically feasible combination:
the photonic system comprises a single photodetector coupled to a waveguide;
the filters are coupled elementary filters;
the photonic device is a tunable laser;
the photonic device is an optical router;
the laser source comprises a plurality of lasers emitting a plurality of emission frequencies;
adjustment devices associated with the source lasers are controlled to modulate the source emission frequencies, and adjustment devices associated with the filters are controlled to adjust the resonant frequency of the filters.

### BRIEF DESCRIPTION OF THE DRAWINGS

Other features and advantages of the invention will emerge from the following detailed description of the invention with reference to the appended figures, in which:

FIGS. 1a, 1b, 1c, 1d, 1e and 1j show schematic diagrams of the principles underlying the invention;

FIG. 1f shows a locking device which can implement a method according to the invention;

FIG. 1g shows a first part of a locking device which can implement a first operating mode;

FIGS. 1h, 1i show two variants of the processes implemented by the locking device in FIG. 1g;

FIGS. 2a to 2d show variants of a first embodiment of the invention, using time-division multiplexing;

FIGS. 3a to 3d show variants of a second, frequency-division multiplexed, embodiment of the invention;

FIGS. 4a to 4h show a first embodiment of a method according to the invention;

FIGS. 5a, 5b show a second application of a method according to the invention;

FIGS. 6a, 6b show a third application of a method according to the invention.

### DETAILED DESCRIPTION OF THE INVENTION

### Principle of the Invention

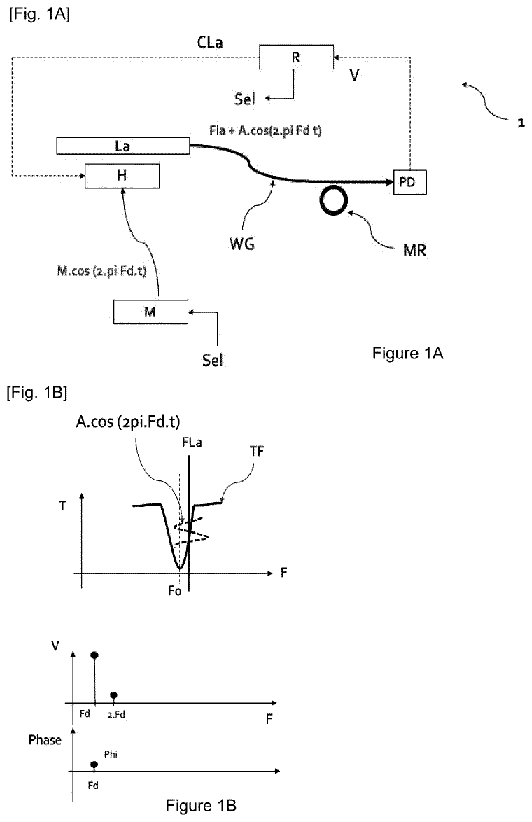

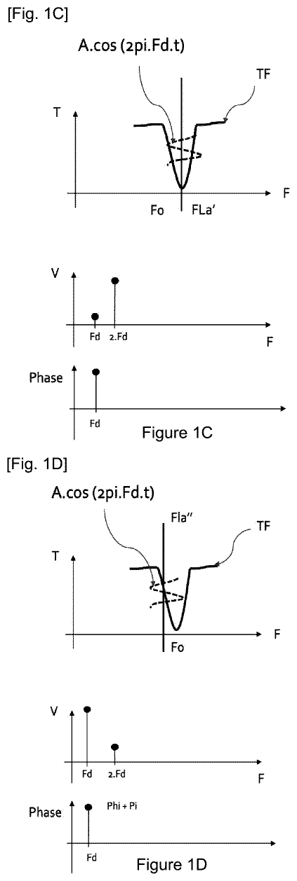

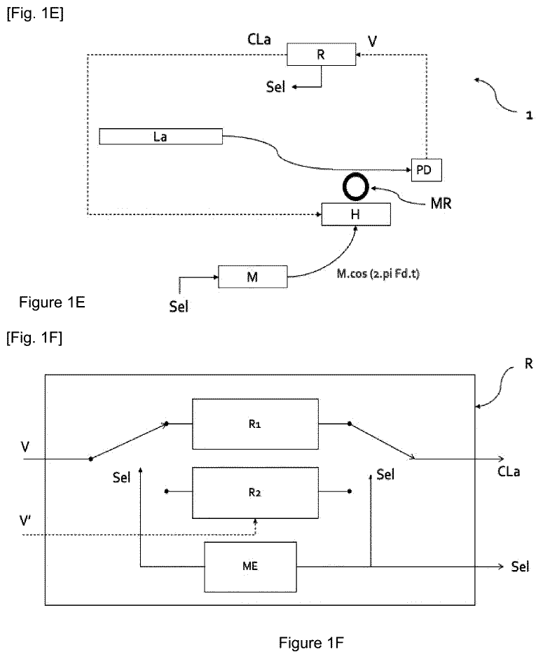

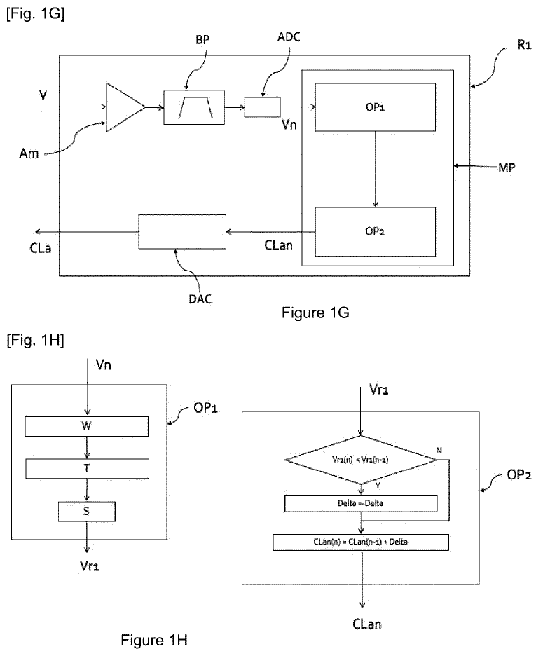

FIGS. 1a, 1b, 1c, 1d and 1e are schematic diagrams of the principles underlying the invention. In the architecture of the photonic system shown for example in FIG. 1a, light radiation from a tunable laser La is guided to a ring resonator MR, forming a filter with a resonant frequency F0, and to a photodetector PD downstream of the resonator MR. To this end, the photonic system includes a waveguide WG configured to optically couple the radiation produced by the laser source La to the filter MR and photodetector PD.

In the example shown in FIG. 1a, the laser source La is a tunable laser. The term “tunable laser” refers to a laser that produces a light radiation whose frequency (the “emission frequency”) can be adjusted via a device H for adjusting the emission frequency. This adjustment device H can be configured to modify the source supply current, operating temperature, optical index and/or free carrier concentration. A tunable laser can be provided with a plurality of devices for adjusting its emission frequency, e.g., an adjustable current source and a heater for modifying the laser's operating temperature.

A modulator M, connected to the laser emission frequency adjustment means, is configured to modulate the emission frequency Fla of the light radiation emitted by the tunable laser La, by a modulation frequency Fd. This modulation frequency Fd, for example 5 kHz, is relatively low compared to the laser emission frequency, for example 200 terahertz. The amplitude of this modulation is also low, of the order of a gigahertz. By way of example, 1 mA of modulation amplitude of the laser source supply current La can lead to a variation in the emission frequency FLa of the order of plus or minus 1 GHz. The frequency of the light radiation emitted by the tunable laser La therefore varies at very low frequency Fd and with low amplitude A (1 GHz) around its fundamental frequency FLa. The laser frequency therefore varies as Fla+A.cos (2pi.Fd.t).

The modulator M can be selectively activated via a selection signal SEL, that is, depending on the state of this signal, the modulator M is activated and effectively modulates the laser emission frequency La, or the modulator is deactivated and does not modulate the laser emission frequency La.

FIG. 1b shows the frequency-domain transmission function T of the filter MR, whose spectrum TF has a resonant frequency F0, and the signal V supplied by this photodetector PD in the case where the emission frequency FLa of the tunable laser La is not locked to a resonant frequency F0 of the resonator MR, but has an emission frequency Fla higher than this resonant frequency F0. Since the emission frequency of the tunable laser La is located in a relatively linear section of the transmission function of the resonator MR, the control signal V provided by the photodetector PD has, in the frequency domain, a main component Fd (corresponding to the modulation frequency) that is relatively large with respect to its harmonics, and in particular with respect to its second harmonic 2*Fd. In addition, the phase Phi of the main component Fd of the control signal V is reduced, that is, this main component is in phase with the modulation signal supplied by the modulator M.

Similar to FIG. 1b, FIG. 1c shows the transmission function T of the filter MR, whose spectrum TF has a resonant frequency F0, and the control signal V supplied by this photodetector PD in the case where the emission frequency FLa′ of the tunable laser La is aligned with the resonant frequency F0 of the resonator MR. In this case, the emission frequency FLa′ of the tunable laser La is arranged in a relatively non-linear section of the transmission function of the resonator MR. As a result, the control signal V provided by the photodetector PD has, in the frequency domain, a second harmonic component 2*Fd relatively large relative to the modulation frequency Fd.

Finally, FIG. 1d shows the frequency-domain transmission function T of the filter MR, whose spectrum TF has a resonant frequency F0. and the control signal V supplied by this photodetector PD in the case where the emission frequency FLa of the tunable laser La is not locked on a resonant frequency F0 of the resonator MR, but has an emission frequency Fla″ lower than this resonant frequency F0. As the emission frequency of the tunable laser La is located in a relatively linear section of the transmission function of the resonator MR, the control signal V supplied by the photodetector PD has, in the frequency domain, a main component Fd that is relatively large with respect to its harmonics, and in particular with respect to its second harmonic 2*Fd. Furthermore, the phase Phi+Pi of the main component Fd of the control signal V is significant, that is, this main component is in phase opposition with the modulation signal provided by the modulator M.

FIG. 1j summarizes the results of FIGS. 1b, 1c and 1d and shows, in the upper graph, the evolution of the power present in the main component Fd and in the second harmonic 2*Fd of the signal V supplied by the photodetector when the emission frequency FLa of the tunable laser La is modified and the resonant frequency of the filter remains fixed (or vice versa). FIG. 1j also shows, in the lower graph, the evolution of the phase of the main component Fd of the signal V supplied by the photodetector.

Returning to the description of the schematic diagram in FIG. 1a, a locking device R receives the control signal V supplied by the photodetector PD and processes it to produce a command CLa for the tunable laser La to tune its emission frequency to lock it to the resonant frequency F0 of the resonator MR. The locking device R also generates the selection signal Sel, enabling the modulator M to be activated or deactivated. Optionally, the locking device can have an additional input V′ for collecting a value representative of the power emitted by the laser, e.g., via a photodetector located close to the laser La, on an optical path located upstream of the filter MR.

FIG. 1f shows a locking device R in one of its modes of operation. This device comprises a first part R1 suitable for operating the photonic system 1 in a first operating mode, during which the modulator M is activated. In this first operating mode, the selection signal Sel is therefore activated by the locking device R. Also in this first mode, the locking device R generates an adjustment command from a first locking signal Vr1 representative of the power of a second harmonic of the modulation frequency present in the control signal V. This first mode of operation is described in detail in a later section of this document, but generally speaking, as explained in relation to the description of FIGS. 1b, 1c and 1d, this mode of operation exploits the result that, when the control signal has a maximum second harmonic 2*Fd, the emission frequency Fla and the resonant frequency F0 match.

Although this mode of operation is particularly efficient, the modulator can lead to disruption of payload data transmission channels.

Also, to avoid continuous operation of the control device in the first operating mode, the locking device R also comprises a second part R2 capable of operating the photonic system 1 in a second operating mode wherein the modulator M is deactivated. In this second operating mode, the selection signal Sel is therefore deactivated by the locking device R. Also in this second mode, the locking device R generates an adjustment command CLa from a third locking signal representative of the power present in the control signal V. This second part can implement a gradient method, that is, produce an adjustment command CLa aimed at maximizing the control signal V. When the locking device R has an additional input V′ for collecting a quantity representative of the power emitted by the laser, the gradient method can be applied to a function taking into account the control signal V and the additional input V′: this can be the difference V′-V, or the ratio V/V′ of these two quantities, which can be maximized or minimized.

The second part R2 capable of implementing the second operating mode may correspond to a microcontroller, a signal processing microprocessor, an FPGA or any other computing device. This computing device may be the same as the one operated in the first part R1 of the locking device, as will be detailed in a forthcoming section of this disclosure. The gradient steps implemented by the computing device in the second operating mode are well known per se and do not require further explanation.

The locking device R also includes a state machine ME producing the selection signal Sel for switching between the two operating modes. By way of example, the state machine ME can be configured to operate the locking device in the first operating mode when the system is started up and for a predetermined period of time, and then to switch to the second operating mode.

This switchover can be based on a criterion other than elapsed time: for example, it can be a criterion of locking performance, for example when the control signal reaches a target value or when measurements extracted from this control signal reach a target value.

The switchover to the second operating mode may be permanent. Alternatively, the state machine ME of the locking device R can alternate between the first operating mode and the second operating mode, either regularly or according to the evolution of a performance criterion.

A photonic system equipped with such a locking device benefits both from the performance of the first mode of operation, which locks the system 1 into nominal operation, and from the fact that it is not permanently affected by transmission disturbances caused by the operation of the modulator M.

### First Part R1 of the Locking Device

This first part R1 of the locking device is shown in FIG. 1g and comprises a first conditioning section for the control signal V supplied by the photodetector PD. This first section includes an amplifier Am, a filter BP and a digital converter ADC, and supplies a digital control signal Vn. In this section, the control signal V supplied by the photodetector PD is received by the amplifier Am, for example a transimpedance or logarithmic amplifier. The amplified control signal V is applied to the filter BP, for example a bandpass filter extending over a working frequency range defined by a minimum and a maximum cutoff frequency. The working frequency range is chosen to incorporate the modulation frequency and its second-order harmonic, that is, the maximum cutoff frequency is chosen to be at least twice the modulation frequency Fd. The signal produced by the filter is sampled by an ADC analog-to-digital converter, to provide a digital control signal Vn, the sampling frequency being chosen to be greater (e.g., 2 to 10 times greater) than twice the maximum cut-off frequency of the filter BP, that is, much greater than four times the modulation frequency Fd. By way of illustration, when the modulation frequency (or maximum modulation frequency, when several frequencies are used, as will be explained in a later section of this description) is 30 kHz, a sampling frequency of 128 kHz or higher may be chosen.

The digital control signal Vn is processed by a computing device MP, which may be a microcontroller, a signal processing microprocessor, an FPGA or any other computing device. The computing device generates at least one digital signal, known as the “locking signal,” to form the adjustment command CLa for the frequency adjustment device. In the example shown in FIG. 1f, this adjustment control CLa is formed by a second conditioning section of a digital adjustment control CLan, the second conditioning section here consisting of a digital-to-analog converter DAC.

Of course, the first and second conditioning sections could comprise other elements, either in addition to or in place of those shown by way of example in FIG. 1g. In particular, converters ADC and DAC can be integrated into the computing device MP and not into the signal conditioning sections.

In very general terms, the computing device MP implements processing using the results presented in FIGS. 1b, 1c, 1d to determine a command CLa to be applied to the laser emission frequency adjustment means H, aimed at maximizing the portion of the signal present in the second harmonic 2*Fd of the control signal supplied by the photodetector PD. As explained in relation to the description of these FIGS. 1b, 1c and 1d, when this part of the signal present in the second harmonic 2*Fd is at its maximum, the system is well locked, that is, the emission frequency Fla and the resonant frequency F0 match. Note that the proportion of the signal present in the main component and the proportion of the signal present in the second harmonic 2*Fd are related to one another, as can be clearly seen in FIG. 1j, so one and/or the other can be exploited as required. It should also be noted that phase can be used to complement either of these signal shares.

Generally speaking, the control CLa is determined by optimizing a function that takes into account the proportion of the signal present in the main component and/or in the second harmonic 2*Fd and/or of a main component Fd of the control signal V. The optimization criterion may be that the function reaches a target value, is below a predetermined ceiling value, or is above a predetermined threshold value.

For example, the ratio between the share of the signal present in the second harmonic and the share of the signal present in the main component Fd can be set to equal a target value or to maximize it.

For the sake of precision, it will be said that the system is “locked” when the chosen optimization criterion is satisfied. This may correspond to the situation where the emission frequency Fla and the resonant frequency F0 match, or where these frequencies are offset from one another by a specified distance.

Returning to the description in FIG. 1g, the processes implemented by the computing device MP include:
A first operation OP1 for processing the digital control signal to produce at least one digital signal Vr1, called “first locking signal,” representative of the power of a second harmonic of the modulation frequency present in the digital control signal Vn;
A second processing operation OP2 of the first locking signal Vr1 to produce a digital adjustment command CLan, the second processing operation OP2 aiming to optimize an optimization function taking into account the first locking signal Vr1.

For example, the second processing operation OP2 may aim to maximize the amplitude of the first locking signal Vr1.

FIG. 1h shows the operations OP1, OP2 implemented by the computing device MP according to a first approach. The first operation OP1 for processing the digital control signal Vn thus comprises a first time windowing step W followed by a second frequency domain transformation step T. This second step T may be a fast Fourier transform, but any other digital transformation in the frequency domain may be suitable. This transformation can provide a spectral distribution of power and phase, although only the power information is exploited in the first approach shown in FIG. 1g. As is well known, the purpose of the windowing step W is to determine the portion of the digital control signal Vn to which the frequency transformation is to be applied and, optionally, to condition this sequence. It can be a simple rectangular window, or a Hanning or Hamming window. The length of this time window, that is, the number of time samples retained in the portion of the digital control signal Vn to which the frequency transformation applies, defines the frequency resolution of the signal produced at the end of the transformation step T, and therefore the possibility of discriminating the power present in a range of frequencies. By way of illustration, a length of 1024 samples gives a resolution of 125 Hz in the digital signal produced by the transformation step T when the sampling frequency is 125 KHz. Resuming the description of the first operation OP1 shown in FIG. 1g, the transformation step T is followed by a selection step S, during which the sample corresponding to the second harmonic 2Fd of the modulation signal Fd is selected from the signal produced by the transformation step. This selection step S therefore leads to the production of a digital signal Vr1, referred to as the “first locking signal” in the remainder of this description, this first locking signal being representative of the power of a second harmonic of the modulation frequency present in the digital control signal Vn. When the control signal V incorporates several modulation signals, as will be detailed in the remainder of this description, the selection step produces a plurality of samples, each sample corresponding to the second harmonic of one of the modulation signals. In this case, the first operation OP1 provides a plurality of first locking signals, each signal being associated with a particular modulation signal.

The first locking signal Vr1 may correspond to the power of a second harmonic of the modulation frequency present in the digital control signal Vn. More generally, this locking signal can correspond to any function taking this second harmonic power as an argument. In particular, this function can be the ratio between the proportion of the signal in the second harmonic and the proportion of the signal present in the fundamental frequency.

FIG. 1h also shows the second operation OP2 implemented by the computing device MP according to the first approach. This second operation OP2 processes the first locking signal Vr1 generated during the first operation OP1. During a first comparison step, the value of the sample Vr1(n), produced at time n, of the first locking signal Vr1 is compared with the value of the sample Vr1(n−1) produced at the previous time n−1, which has therefore been stored. Depending on the result of this comparison, the digital adjustment command Clan produced at the previous time n−1 is incremented or decremented by a predetermined incremental value Delta, in order to produce this digital command at time n. It is thus understood that this second operation OP2 aims to maximize the amplitude of the first locking signal Vr1 (representative of the power of a second harmonic of the modulation frequency in the digital control signal Vn), by causing the digital adjustment command Clan to evolve, upwards or downwards. When the control signal V incorporates several modulation signals, and therefore as presented in the previous paragraph the first operation produces a plurality of first locking signals Vr1, a plurality of second operations run concurrently, each second operation processing a first locking signal Vr1 from the plurality produced by the first operation.

The second comparison step could be made different from the simple comparison between two successive samples shown in this example, leading to maximizing the amplitude of the first locking signal Vr1. This comparison step is selected according to the chosen optimization criterion, that is, whether the locking signal is to be maximized, minimized or made equal to a given value.

FIG. 1i shows the operations OP1, OP2 implemented by the computing device MP according to a second approach. The first operation OP1 for processing the digital control signal Vn comprises the same first windowing step W and second frequency-domain transformation step T as in the first approach. These steps are followed by two concurrent selection steps S1, S2 producing two locking signals Vr1, Vr2. The first selection step S1 producing the first locking signal Vr1 is identical to the selection step of the first approach. During the second selection step S2, the sample corresponding to the phase of the modulation frequency Fd (the fundamental) is selected from the signal produced by the transformation step. This selection step S2 therefore leads to the production of a digital signal Vr2 referred to as the “second locking signal” in the remainder of this description, this second locking signal being representative of the phase of the fundamental of the modulation frequency present in the digital control signal Vn.

FIG. 1i also shows the second operation OP2 implemented by the computing device MP according to the second approach. This second operation preserves the principle set out in the detailed description of the first approach, according to which the aim is to optimize the amplitude of the first locking signal Vr1, by increasing or decreasing the digital adjustment command Clan. The step of incrementing or decrementing an increment value Delta of the digital adjustment command generated at the previous time n−1 is used to generate this digital command at time n. According to this second approach, however, the sign Si applied to the incrementation value Delta is determined by a comparison step between the second locking signal Vr2 and the phase Phi of the modulation signal. As mentioned earlier, this phase comparison allows us to determine the relative position of the filter's emission frequency and resonant frequency. The increment value Delta is determined by a metric function f applied to the first locking signal Vr1. By way of example, this function can consist in determining the relative proportion of the power present in the second harmonic to the total power measured in the spectrum, or to the power present in the fundamental frequency. Of course, you can also choose to define the second locking signal Vr2 as the difference between the phase of the main component of the modulation frequency present in the digital control signal Vn and the phase Phi of the modulation signal.

When the control signal V incorporates several modulation signals, the same principles apply as in the first approach, which result in a plurality of first and second locking signals Vr1, Vr2 being provided at the end of the first operation OP1, and each pair of locking signals Vr1, Vr2 being processed by an instance of the second operation OP2, these instances of the second operation OP2 running concurrently.

In one variant, the second operation OP2 could be based solely on the processing of the second locking signal Vr2 to produce the digital adjustment command CLan. This second operation OP2 then uses this second locking signal Vr2 to generate the command

CLan. In particular, a first spectral positioning phase based solely on the second locking signal Vr2 can be envisaged, followed by a second spectral positioning phase based on the first locking signal Vr1. This second phase can also exploit the second locking signal Vr2, as described above.

To conclude this section on the general principles applied in the first operating mode, it should be noted that applying a sinusoidal modulation signal with the aid of the modulator M, that is, applying spectrally pure modulation to the emission frequency, limits the appearance of harmonics in the control signal V supplied by the photodetector PD (compared with square-wave modulation, for example). The harmonics detected by the first part R1 of the locking device R are then well representative of the locking quality between the emission frequency and the resonant frequency.

Note also that the same locking principles are applicable to a configuration where the laser has a fixed emission frequency, and where the adjustment device H is associated with the filter MR so as to adjust its resonant frequency. Such a configuration is shown in FIG. 1e. The adjustment device H in this case may be a heater, enabling the filter's operating temperature and hence its resonant frequency to be adjusted.

Finally, the modulator M need not be a separate component of the photonic system 1: it can, for example, be integrated into the locking device R itself, which then generates the modulation signal and applies it to the adjustment device H used to modulate the emission or resonant frequency. If the same adjustment device H is used both to modulate and to adjust the emission frequency of a laser or the resonant frequency of a filter, the locking device R can simply sum the modulation signal and the control signal, and the signal resulting from this sum applied to this single adjustment device H.

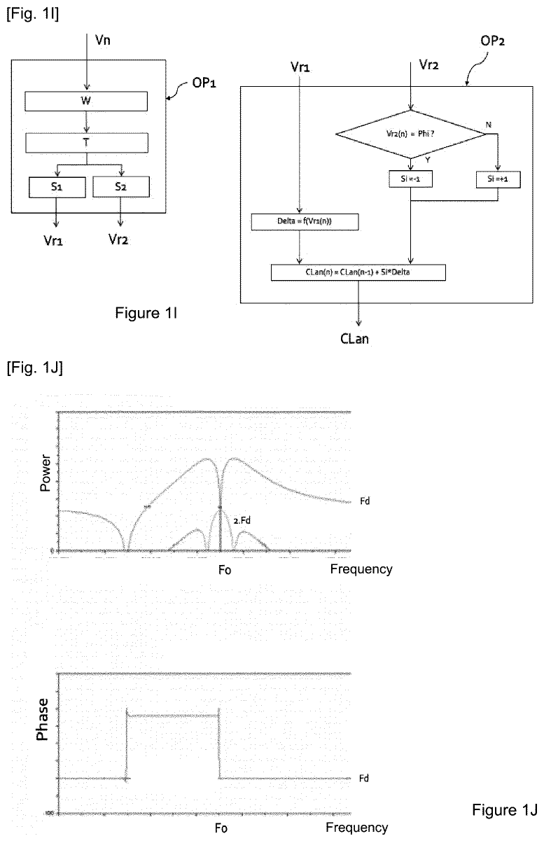

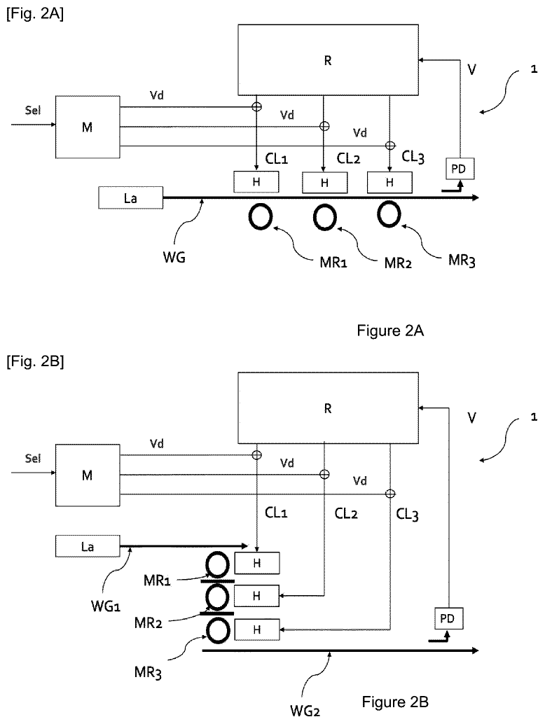

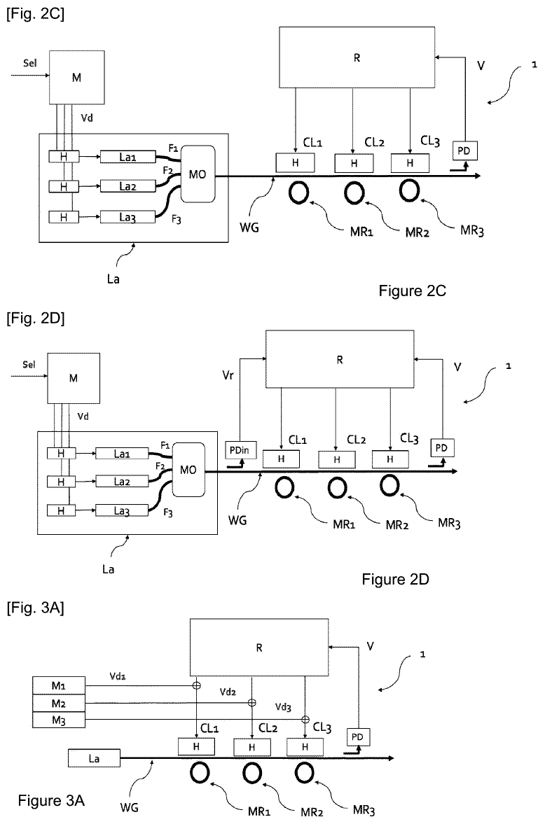

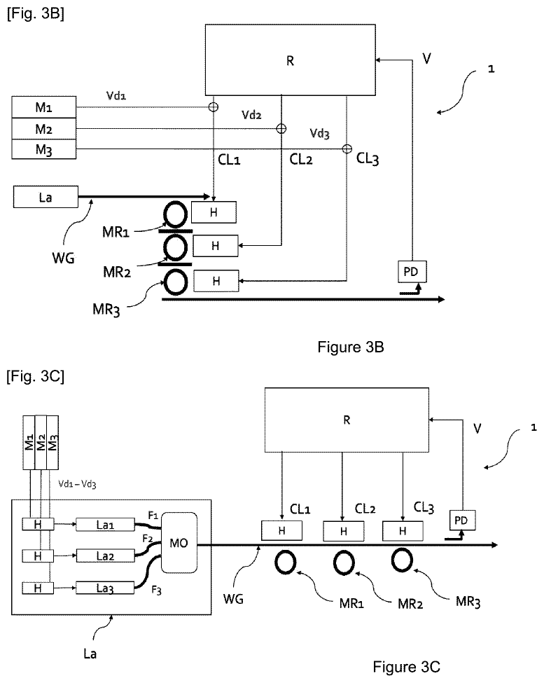

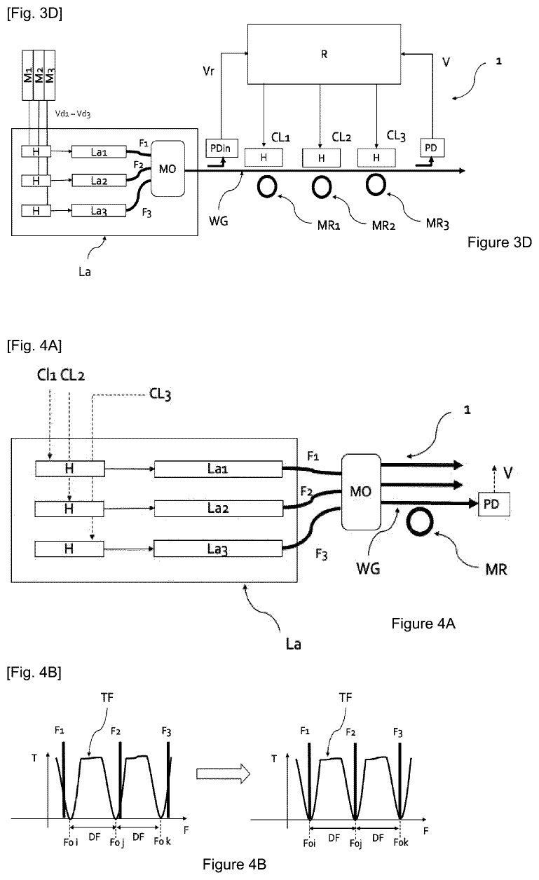

The principles of the first mode of operation of the locking device described above are particularly useful when a plurality of elements in the photonic system 1 need to be locked together. This is particularly the case when the photonic system 1 consists of a plurality of filters, as shown in FIGS. 2a, 2c and 3a. This is also the case when the photonic system is composed of a filter made up of a plurality of elementary filters coupled together, as shown in FIGS. 2b and 3b. In every case, a single photodetector PD is preferably used to adjust and lock together at least one emission frequency of at least one laser source La and at least one resonant frequency of at least one filter MR.

### Time-Division Multiplex Locking

In this first mode of implementation of the first operating mode, the photonic system 1 comprises a plurality of selectively controllable adjustment devices H respectively associated with a plurality of filters or a plurality of laser sources. The spectral positioning method for photonic system 1 includes a step for selecting a single adjustment device H associated with a filter on which locking operations are performed.

In the example shown in FIGS. 2a and 2b, a plurality of micro-ring filters MR1, MR2, MR3 are coupled to a waveguide WG. In these examples, we find a laser source La upstream of a waveguide WG, WG1 and the photodetector PD downstream of this waveguide WG (FIG. 2a) or of a complementary waveguide WG2 (FIG. 2b). The photodetector PD is coupled to the waveguide WG or complementary waveguide to pick up at least part of the light radiation propagating through it. In the example shown in FIG. 2a, the laser source La emits radiation having a plurality of emission frequencies, and we seek to tune each filter MR1, MR2, MR3 to one of the emission frequencies of the laser source La. In the example shown in FIG. 2b, the laser source emits light radiation which may have a single emission frequency or a plurality of emission frequencies, and we seek to tune each elementary filter MR1, MR2, MR3 to one of the laser source's emission frequencies in order to adjust the filter's overall transfer function.

A modulator M produces a modulation signal Vd, preferably spectrally pure and therefore with a single modulation frequency Fd. This modulation signal is selectively applied to only one of the adjustment devices H, in this case heaters, by means of a selection signal Sel.

At the same time, the locking device R receives the control signal supplied by the photodetector PD and supplies a control signal CL1, CL2, CL3 to the selected adjustment device H. The locking device R is thus configured to control the modulator M and to select, by means of the selection signal Sel, the adjustment device H to which the modulation signal Vd and the command signal CL1, CL2, CL3 is applied. The locking device thus selects the filter MR1, MR2, MR3 whose resonant frequency is tuned.

FIG. 2c shows another example of a time-division multiplex implementation. In this particularly advantageous example, a single emission frequency is modulated by means of the modulation signal Vd applied by the modulator M to an adjustment device H associated with a laser of the source La. The locking device R receives the control signal V supplied by the photodetector PD and controls an adjustment device H associated with a filter MR1, MR2, MR3 so as to adjust and lock the resonant frequency of this filter to the selected laser emission frequency.

The laser source La comprises a plurality of lasers La1, La2, La3 emitting radiation with distinct emission frequencies F1, F2, F3. Each laser can be associated with an adjustment device H, preferentially consisting of its current source. The radiation from the lasers is combined by an optical mixer MO to produce multispectral light radiation with a plurality of emission frequencies. The modulation signal Vd is selectively applied to the adjustment device H associated with one of the lasers La1, La2, La3 of the source La, whose emission frequency is then modulated. At the same time, the locking device R receives the control signal supplied by the photodetector PD and supplies a control signal CL1, CL2, CL3 to the adjustment device H associated with one of the filters MR1, MR2, MR3, so as to lock it to the laser emission frequency.

FIG. 2d shows a variant of the example shown in FIG. 2c, which is particularly suitable when the laser source La and the filters MR1, MR2, MR3 are made up of separate photonic components that cannot communicate with one another. In this variant, a portion of the multispectral light radiation propagating on the waveguide WG is sampled upstream of the plurality of filters MR1, MR2, MR3. An input photodetector PDin measures this part of the light radiation in order to produce a reference signal Vr and supply it to the locking device R.

In this case, the locking device R can combine the information present in the control signal V and the reference signal Vr to produce the first locking signal Vr1 and/or the second locking signal Vr2.

After transforming the reference signal Vr in the frequency domain (e.g., using a fast Fourier transform), these processes can seek to establish the phase and power present in the fundamental and/or in the second harmonic of the modulation frequency present in the reference signal Vr.

The first locking signal Vr1 can then be constructed as the ratio of the power present in the fundamental (modulation frequency Fd) of the reference signal to the power present in the fundamental of the control signal. Alternatively, the first locking signal Vr1 can be defined as the ratio of the power present in the second harmonic of the modulation frequency Fd of the reference signal Vr to the power present in the second harmonic of the modulation frequency Fd of the control signal V. More generally, the first locking signal Vr1 can combine any information extracted from the control signal V and the reference signal Vr. The same principles can be used to form a second locking signal Vr2 combining the phase information at the modulation frequency Fd (the fundamental) of the reference signal Vr and the control signal V. This may involve taking the difference between these two phases.

The second locking signal Vr2 may correspond to the difference between the phase of a main component of the modulation frequency Fd present in the digital control signal Vn and the phase of the reference signal (Vr).

In all the examples shown in FIGS. 2a to 2d of this time-division multiplexed locking, the state machine of the locking device R can be configured to set the selection signal Sel circularly selecting one of the adjustment devices H connected to the modulator M, for example during successive locking periods whose duration can typically be between a few microseconds and a few milliseconds. During each locking period, the locking device R implements the locking operations described above, locking the resonant frequency F0 of the filter or elementary filter to a laser emission frequency La. At the end of a complete cycle, each filter or elementary filter MR1, MR2, MR3 is locked onto a laser emission frequency La.

### Frequency Multiplex Locking

In this second mode of implementation of the first mode of operation, the photonic system 1 also comprises a plurality of respective adjustment devices H associated with a plurality of filters MR1, MR2, MR3 and/or a plurality of lasers La1, La2, La3. The locking device R also concurrently generates a plurality of control signals CL1, CL2, CL3, each control signal being applied to a filter adjustment device H. To enable this, the modulation frequencies Vd1, Vd2, Vd3 applied to the adjustment devices H by a plurality of modulators M1, M2, M3 are distinct from one another.

FIGS. 3a to 3d show the photonic system 1 of the previous examples, comprising the plurality of micro-ring filters MR1, MR2, MR3 and the heaters H associated with these filters. In the case of FIG. 3a and FIG. 3c, the laser La produces radiation with a plurality of emission frequencies. In the case of FIG. 3b, the laser La produces radiation with a single emission frequency. In both examples, the single photodetector PD produces the control signal V.

In the embodiment shown in FIGS. 3a to 3d, the filters or elementary filters MR1, MR2, MR3 are simultaneously locked to a laser emission frequency La by frequency multiplexing. To this end, the system comprises a plurality of modulators M1, M2, M3, each modulator producing a modulation signal Vd1, Vd2, Vd3, preferably spectrally pure, and therefore having a single modulation frequency. This single modulation frequency is distinct from one modulator to another, so that the resonant frequencies of the filters (FIGS. 3a, 3b) or the emission frequencies of the lasers (FIGS. 3c, 3d) are modulated using distinct modulation frequencies, making it possible to locate them in the line spectrum produced by the locking device R, during the first operation OP1. For example, the modulation frequencies can be comprised and stepped within the range 1 KHz to 30 KHz. In the case of this embodiment, it is therefore not necessary for the modulators M1, M2, M3 to be controllable via a time selection signal. Modulation frequencies should be chosen so that they are not only distinct from one another, but also from their second harmonics, to avoid spectral overlap between a modulation frequency and a second harmonic of another modulation frequency. In the example shown in FIG. 3d, the photonic system 1 is equipped with an input photodetector PDin to measure part of the light radiation propagating on the waveguide WG, upstream of the optical filters MR1, MR2, MR3 and to produce a reference signal Vr, supplied to the locking device R.

The locking device R can combine the information present in the control signal V and the reference signal Vr to produce the first locking signal Vr1 and/or the second locking signal Vr2, as explained in an earlier passage.

The processes implemented by the first part R1 of the locking device R are naturally adapted to this embodiment, but are based on the same principles described above. In particular, the processing operation makes it possible to identify the lines (fundamental and harmonic) in the spectrum, to prepare a plurality of first locking signals and associate them with the respective filters. The first part R1 of the locking device R is also configured to implement a plurality of operations, respectively associated with the locking signals, to concurrently produce a plurality of adjustment commands CL1, CL2, CL3 of the adjustment devices H associated with the filters MR1, MR2, MR3.

### First Exemplary Application

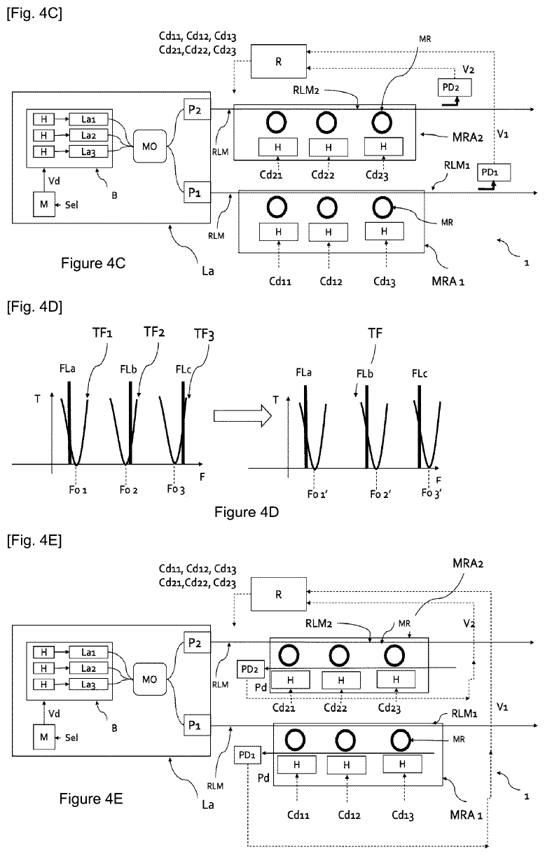

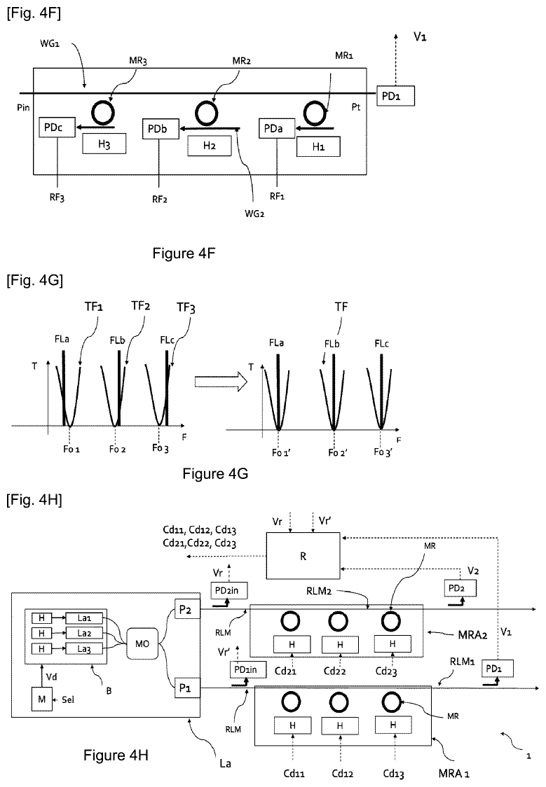

FIG. 4a shows an application example of a photonic device 1 that can benefit from a spectral positioning method in accordance with the invention. In this illustration, the laser source La consists of a bank of lasers La1, La2, La3, each emitting radiation with an emission frequency F1, F2, F3 distinct from the other lasers. These rays are recombined by a mixer MO to produce a plurality of light rays, each ray combining emission frequencies F1, F2, F3. One of these rays is exploited, at least in part, by coupling to a filter MR, then to the photodetector PD via a waveguide WG. The filter MR has a plurality of regularly spaced resonant frequencies F0i, F0j, F0k.

Each laser La1, La2, La3 is associated with a respective current source producing its supply current, each source forming a laser emission frequency adjustment device within the meaning of the invention. Modulating or adjusting the current produced by a current source modulates or adjusts the frequency of the associated laser. As already mentioned, the adjustment device can take other forms than the one used here as an example.

As can be seen on the left-hand side of FIG. 4b, the emission frequencies of the bank's lasers are not necessarily uniformly separated in frequency, and this variable spectral deviation from one pair of lasers to another can be problematic. To correct this and obtain the configuration shown on the right-hand side of FIG. 4b, the photonic device can be fitted with a locking device R implementing the operations constituting the spectral positioning method of the invention. The locking device R can operate in either the first (time-division multiplexing) or second (frequency-division multiplexing) mode. During operation of the photonic system thus formed, the laser emission frequencies are adjusted to the resonant frequencies of the filter MR, and the spectral deviation is regularized.

FIG. 4c shows a variant of the first application example. The laser source La has at least one output port (two ports P1, P2 in FIG. 4c), each producing multispectral light radiation RLM. This radiation is thus spectrally composed of a plurality of lines separated by a spectral interval that may be variable. At least one of these lines is frequency-modulated, as has been explained in detail in connection with the description of FIGS. 2c and 3c.

Each laser La1, La2, La3 is associated with a current source H, forming means for adjusting its emission frequency, connected to the modulator M. The lasers La, Lb, Lc are coupled to an optical mixer MO via a network of waveguides internal to the source La. The multispectral light radiation RLM produced by the optical mixer MO is guided by the internal waveguide network to a port P1, P2 on source La. It propagates in an external waveguide coupled to this port P1, P2.

The external waveguide is itself coupled to a photonic component MRA1, MRA2, arranged optically downstream of source La, on port P1, P2 of the component, the photonic component comprising a plurality of optical filters MR having individually tunable resonant frequencies, respectively.

In the example shown in FIG. 4c, two radiofrequency modulators MRA1, MRA2, each implementing an array of micro-resonators, are respectively optically connected to two ports P1, P2 of the laser source La. As is well known in the field of telecommunications, a radiofrequency modulator is used to condition each spectral line of multispectral light radiation (here by means of micro-resonators respectively tuned to these lines) in order to transmit information signals in a frequency-division multiplexed manner. But this aspect of the invention is by no means limited to photonic components implementing a radiofrequency modulator, and applies to any photonic component featuring a plurality of optical filters which it may be advantageous to lock onto frequencies of light radiation.

To enable locking of the photonic system S, the resonators MR of the resonator network of the radiofrequency modulators MRA1, MRA2 are respectively associated with heaters H, forming adjustment devices for adjusting their resonant frequency, in particular for locking them to the spectral lines with which they are associated. In this way, the optical component MRA1, MRA2 can be tuned to the source La. A single monitoring photodetector PD1, PD2 is also provided optically downstream of the photonic component MRA1, MRA2 in order to establish an electrical signal V1, V2 representative of the multispectral radiation RLM1, RLM2 produced by this component. For this purpose, a small portion of this multispectral radiation RLM1, RLM2 can be sampled and coupled to the monitoring photodetectors PD1, PD2.

A locking device R collects the signal V1, V2 supplied by the monitoring photodetector PD1, PD2 and produces the control signals Cd11, Cd12, Cd13; Cd21, Cd22, Cd23 enabling the adjustment devices H of the optical filters MR making up the photonic component MRA1, MRA2 to be controlled, and therefore to individually adjust their resonant frequencies in order to lock onto the emission frequencies of the source La.

In the photonic system 1 comprising a radiofrequency modulator, the aim is to position the resonant frequency F01, F02, F03 of each micro-resonator MR relative to a spectral line FLa, FLb, FLc of the multispectral radiation produced by source La, according to the configuration shown in FIG. 1a, that is, in a linear part of the transfer function TF1-TF3 of the micro-resonator MR. Naturally, the aim is to allocate a distinct emission line to each micro-resonator. As shown in FIG. 4d, the adjustment means H associated with the micro-resonators MR are used to adjust the original resonant frequencies F01, F02, F03 to these optimized frequencies F01′, F02′, F03′.

FIG. 4e shows another variant of the example shown in FIG. 4c. In this variant, the modulator has an output loss port (“drop port”) Pd. The monitoring photodetector PD1, PD2 is directly coupled to the loss output port Pd.

FIG. 4f shows a demodulator, this demodulator forming another type of optical component MR1, MRA2 that can be calibrated/locked in accordance with the principles of the invention. In such a demodulator, each micro-resonator in the micro-ring resonator MR1-MR3 array is arranged between a first and a second waveguide WG1, WG2. The first waveguide WG1 has an input port Pin, to which the multispectral light radiation to be demodulated can be supplied, and a transmission port Pt. The loss ports of micro-resonators MR1, MR2, MR3 are connected to demodulation photodetectors PDa, PDb, PDc. The photodetector PD1 is placed on the first waveguide WG1 at the transmission port Pt. Each micro-resonator MR1-MR3 filters and extracts radio frequency signals RF1, RF2, RF3 from the multispectral light beam, respectively carried by the emission frequencies (referred to as “carrier frequencies” in this context) FLa, FLb, FLc of the multispectral light radiation. A means H1-H3, such as a heater, for adjusting the resonant frequency F01-F03, is also associated with each micro-resonator MR1-MR3.

FIG. 4g shows, on the left of the figure, the relative positioning of resonant frequencies F01, F02, F03 of filters MR1, MR2, MR3 and carrier frequencies FLa, FLb, FLc, before adjustment. Also shown on the right of this FIG. 4g is the relative positioning of the adjusted resonant frequencies F01′, F02′, F03′ and the carrier frequencies FLa, FLb, FLc, after adjustment and in the case where it is deliberately chosen to lock the micro-resonators MR1, MR2, MR3 to the closest optical carriers FLa, FLb, FLc.

Of course, the photonic system 1 can also be equipped with an input photodetector PDin1, PDin2 associated with each external waveguide upstream of the photonic device MRA1, MRA2, as shown in the schematic diagrams of FIGS. 2d, 3d. This variant is shown in FIG. 4h. Each input photodetector PDin1, PDin2 produces a reference signal Vr, Vr′ which can be exploited by the locking device R, as described in an earlier section of this description.

The locking device R of the variants shown in FIGS. 4c, 4e and 4f is operated in time-division multiplex mode. This variant can also be used for frequency multiplexing, with modulators simultaneously generating a plurality of different modulation signals, as described in FIG. 3c.

Whatever the nature of the photonic components MRA1, MRA2 associated with the source La, it may be advantageous to engage the system implementation, during a start-up phase, in a frequency multiplexing operation wherein a distinct modulation frequency is applied to each emission/carrier frequency Fla, Flb, FLc of the multispectral light radiation RLM. For simplicity of implementation, it can be decided to produce one after the other, in order to adjust the resonant frequency of one optical filter at a time, the control signals enabling independent control of the adjustment devices H of each micro-resonator MR1, MR2, MR3. As already stated, this method of implementation makes it possible to control the association of a micro-resonator with a carrier frequency, whereas prior art solutions could lead to the association of several micro-resonators with the same carrier frequency. Once this start-up phase has been completed, it can be decided to generate the control signals concurrently.

### Second Exemplary Application

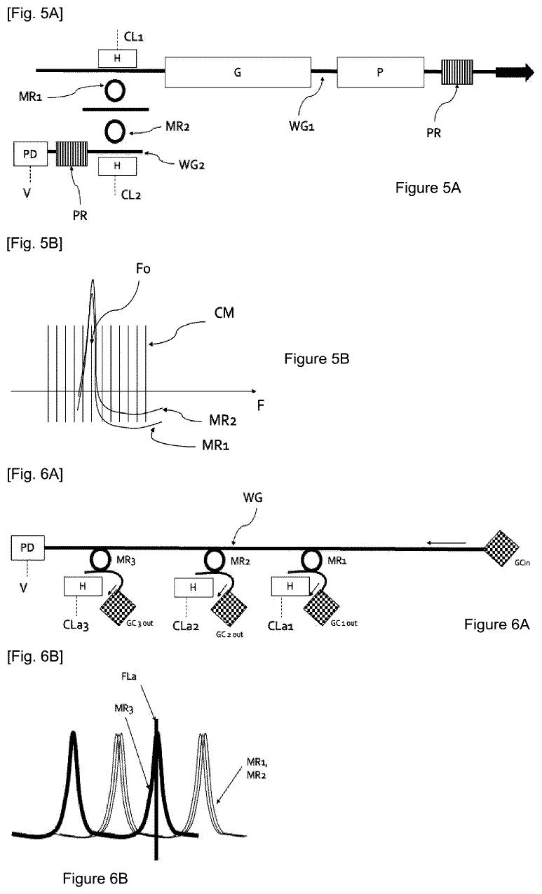

FIG. 5a shows another photonic device that can benefit from a spectral positioning method according to the invention. In the figure, this device consists of a tunable laser comprising a gain zone G and a phase zone P. The phase zone P can be constituted, for example, by a heater of a waveguide section, and the gain zone G is supplied with current, as is well known per se, in order to cause the emission of light radiation guided by at least one waveguide WG1, WG2 between two reflectors PR defining a cavity, these reflectors being partial and letting through a portion of this radiation, for example of the order of 90%. In this optical cavity, two elementary filters MR1, MR2 are positioned, each of these filters being associated with a frequency adjustment device H1, H2, for example a heater. These elementary filters enable precise selection of one of the laser cavity's emission frequencies (the laser cavity's emission frequencies are commonly referred to as the cavity's “modes”), by tuning each of the elementary filters' resonant frequencies to the chosen mode of the laser's emission frequency.

The photonic device shown in FIG. 5a can be fitted with a locking device R which implements both (or at least one) of the operating modes constituting the spectral positioning method of the invention. The locking device R can operate indifferently in the first mode of operation according to the first mode of implementation (by time-division multiplexing) or according to the second mode of implementation (by frequency-division multiplexing). During operation of the photonic system thus formed, the resonant frequencies of the elementary filters MR1, MR2 are each locked to the chosen emission frequency CM (cavity modes) of the laser defining its emission mode, as shown in FIG. 5b.

### Third Exemplary Application

FIG. 6a shows yet another photonic device that can benefit from a spectral positioning method according to the invention. In this figure, a photonic router includes a laser source, represented here by a GCin input coupler for receiving light radiation emitted by a laser external to the device. The received light radiation is guided by a waveguide WG to a photodetector PD. Along the waveguide WG, a plurality of filters MR1, MR2, MR3 are arranged between this waveguide and output couplers GC1out, GC2out, GC3out. Each filter is associated with an adjustment device H1, H2, H3, such as a heater.

In operation, the photonic device allows light radiation received on the input coupler to be directed to a selected output coupler. To enable this choice, the adjustment device locks the resonant frequency of the filter associated with the selected output coupler to the emission frequency of the laser radiation. At the same time, the resonant frequencies of the other filters associated with the unselected output couplers are misaligned with the laser source's emission frequency. This operation is shown in FIG. 6b, where, by way of example, the light radiation is guided to one of the output couplers GC3out by locking the emission frequency Fla to the resonant frequency of the filter MR3 associated with the chosen output coupler GC3out. At the same time, the other two filters MR1, MR2 are misaligned with the laser's emission frequency Fla. In this way, the light beam propagating in the waveguide WG is coupled to the single output coupler selected.

The photonic device shown in FIG. 6a can be fitted with a locking device R in accordance with the invention. The locking device R can operate indifferently in the first mode of operation according to the first mode of implementation (by time-division multiplexing) or according to the second mode of implementation (by frequency-division multiplexing). During operation of this photonic system thus established, the resonant frequency of the filter associated with the selected output coupler is locked onto the laser emission frequency, while the other filters are misaligned.

Naturally, the invention is not limited to the embodiments described, and it is possible to add alternative embodiments without departing from the scope of the invention as defined by the claims.

In particular, although filters in the form of resonant rings have been used in the examples, this is by no means a limitation of the invention, which can be applied to any form of filter, such as a Mach Zehnder (MZ) interferometer filter. This filter can form, at least in part, a modulator, for example a resonant ring modulator or an MZ modulator.

In addition, the waveguide can be an optical fiber and the laser can be modulated, for example an external laser whose intensity is modulated.

1. A method for spectral positioning of a photonic system, the photonic system comprising
at least one laser source producing radiation with at least one emission frequency;
a plurality of filters each having a resonant frequency;
at least one waveguide configured to optically couple the radiation produced by the laser source to the filters;
a photodetector optically coupled to the waveguide for receiving filtered radiation, the photodetector producing a control signal;
a plurality of adjustment devices associated with the laser source and/or the filters, the adjustment devices being controlled on the one hand to modulate, at a modulation frequency, the at least one emission frequency of the laser source or the resonant frequencies of the filters and on the other hand to adjust the resonant frequency of the filters;
the method implementing the following operations:
conditioning of the control signal to produce a digital control signal;
a first operation for processing the digital control signal to produce at least one digital signal, referred to as the “first locking signal,” representative of the power of a second harmonic and/or of a main component of the modulation frequency present in the digital control signal;
a second operation for processing the first locking signal to produce a digital adjustment command, the second operation aiming to optimize the amplitude of the first locking signal;
conditioning of the digital adjustment command to produce the adjustment command and apply it to the adjustment devices.

2. The method according to claim 1, wherein the first locking signal is representative of the power of a second harmonic of the modulation frequency and the second operation aims to maximize the amplitude of the first locking signal, or the first locking signal is representative of the power of the main component of the modulation frequency and the second operation aims to minimize the amplitude of the first locking signal.

3. The method according to claim 1, wherein the first locking signal is formed by the ratio between the power of the second harmonic of the modulation frequency and the power of the main component of the modulation frequency, the second operation aiming to optimize the amplitude of the first locking signal so that it is equal to or greater than a determined value.

4. The method according to claim 1, wherein the first operation produces at least one second locking signal representative of the phase of a main component of the modulation frequency present in the digital control signal.

5. The method according to claim 4, wherein the second locking signal corresponds to the difference between the phase of a main component of the modulation frequency present in the digital control signal and the phase of a modulation signal or reference signal.

6. The method according to claim 1, comprising a step of selecting a single one of the adjustment devices, the selection step being repeated to successively select each of the adjustment devices.

7. The method according to claim 1, wherein the modulation frequencies of the adjustment devices are distinct from one another.

8. The method according to claim 1, wherein the adjustment command is applied to the adjustment devices, one optical filter at a time.

9. A photonic system for spectral positioning of a photonic device comprising:
at least one laser source producing radiation with at least one emission frequency;
a plurality of filters each having a resonant frequency;
at least one waveguide configured to optically couple the radiation produced by the laser source to the filter;
a photodetector optically coupled to the waveguide for receiving filtered radiation, the photodetector producing a control signal;
a plurality of adjustment devices associated with the laser source; and/or the filters, the adjustment devices being controlled on the one hand to modulate, at a modulation frequency, the emission frequency of the laser source or the resonant frequencies of the filters and on the other hand to adjust the resonant frequency of the filters;
a locking device configured to perform the following operations:
i. conditioning the control signal to produce a digital control signal;
ii. a first operation for processing the digital control signal to produce at least one digital signal, referred to as the “first locking signal,” representative of the power of a second harmonic and/or of a main component of the modulation frequency present in the digital control signal;
iii. a second operation for processing the first locking signal to produce a digital adjustment command, the second operation aiming to optimize the amplitude of the first locking signal;
iv. conditioning of the digital adjustment command to produce the adjustment command and apply it to the adjustment devices.

10. The photonic system according to claim 9, comprising a single photodetector coupled to a waveguide.

11. The photonic system according to claim 9, comprising an input photodetector coupled to a waveguide upstream of the plurality of filters.

12. The photonic system according to claim 9, wherein the filters are coupled elementary filters.

13. The photonic system according to the preceding claim 12, wherein the photonic device is a tunable laser.

14. The photonic system according to claim 9, wherein the photonic device is an optical router.

15. The photonic system according to claim 9, wherein the laser source comprises a plurality of lasers emitting a plurality of emission frequencies.

16. The photonic system according to claim 15, wherein adjustment devices associated with the lasers of the source are controlled to modulate the emission frequencies of the source and adjustment devices associated with the filters are controlled to adjust the resonant frequency of the filters.
